(19) United States
(12) Patent Application Publication
(10) Pub. No.: US 2025/0344355 A1
(43) Pub. Date: Nov. 6, 2025

(54) CONTROL APPARATUS FOR VEHICLE

(71) Applicant: HYUNDAI MOBIS CO., LTD., Seoul (KR)

(72) Inventor: Kyeong Jun LEE, Seoul (KR)

(73) Assignee: HYUNDAI MOBIS CO., LTD., Seoul (KR)

(21) Appl. No.: 19/014,406

(22) Filed: Jan. 9, 2025

(30) Foreign Application Priority Data
May 3, 2024 (KR) 10-2024-0058970

(51) Int. Cl. H05K 7/20; H05K 5/03; H05K 7/14

(52) U.S. Cl. CPC H05K 7/20854; H05K 5/03; H05K 7/1427

(57) ABSTRACT

According to an embodiment of the present disclosure, there is provided control apparatus for a vehicle, the control apparatus comprising: a housing having an internal space therein and an open upper side; a control board mounted inside the housing; a control element positioned on a surface of the control board and including at least one heat-generating component; a heat sink corresponding to a surface of the control board and covering the open upper side of the housing; a base bracket mounted on one side of the housing and contacting the heat sink to release heat to an outside of the control apparatus; and a main bracket in contact with a surface of the base bracket.

### CROSS-REFERENCE TO RELATED APPLICATION

This application claims the benefit of priority to Korean Patent Application No. 10-2024-0058970 filed in the Korean Intellectual Property Office on May 3, 2024 the entire contents of which are incorporated herein by reference.

### TECHNICAL FIELD

The present disclosure relates to a control apparatus for a vehicle, and more specifically, to a control apparatus for a vehicle for securing the fixed rigidity and heat dissipation performance of a control apparatus mounted on a vehicle.

### BACKGROUND

The contents described in this specification simply provide background information on the present disclosure and do not constitute prior art.

A vehicle is equipped with a vehicle control apparatus such as an electronic control unit (ECU) and a microcontroller unit (MCU) that control various devices. Such a vehicle control apparatus receives information from sensors or switches installed in each part of a vehicle, processes the information received in this manner, and performs various control operations to improve the ride comfort and driving safety of the vehicle or provide various conveniences to the driver and passengers.

For example, a vehicle control apparatus is used to control an engine, transmission, air conditioning, AV system, navigation system, wireless communication, etc.

Recently, the demand for high-performance control apparatuses is increasing due to the development of technologies such as autonomous driving and wireless communication. A control apparatus for high-performance vehicles may include a housing, and a printed circuit board (PCB) and a central processing unit (CPU) housed in the housing.

A number of electronic components (electronic control elements) for controlling the vehicle or power supply are mounted on the PCB. As the functions of the vehicle control apparatus become more diverse, a lot of heat may be generated from the electronic components mounted on the PCB.

A high-performance CPU generates a lot of heat as power consumption thereof increases more than three times compared to a conventional CPU.

This heat generation may reduce the reliability and durability of the vehicle control apparatus.

A conventional vehicle control apparatus generally includes heat dissipation fins provided on the outer wall of the housing for heat dissipation. Heat generated from electronic components installed inside the housing is transferred to the housing and released into the atmosphere through the heat dissipation fins installed on the outer wall of the housing.

However, in the case of heat dissipation using heat dissipation fins, the volume and weight of the vehicle control apparatus may increase, which may restrict the shape thereof. In addition, problems such as damage to a controller due to the increased weight of the vehicle control apparatus may occur.

### SUMMARY

An object of the present disclosure is to provide a vehicle control apparatus with improved heat dissipation performance by effectively transferring heat generated from a control element to a heat sink and a base bracket.

An object of the present disclosure is to provide a vehicle control apparatus that is lightweight and has high heat dissipation performance by using a base bracket that replaces conventional heat dissipation fins.

An object of the present disclosure is to provide a vehicle control apparatus for alleviating stress concentration and increasing the degree of freedom of mounting conditions in a vehicle by using a plurality of brackets.

The problems to be solved by the present disclosure are not limited to the problems mentioned above, and other problems not mentioned can be clearly understood by those skilled in the art from the description below.

### ADVANTAGEOUS EFFECTS

According to one embodiment, it is possible to provide a vehicle control apparatus with improved heat dissipation performance by effectively transferring heat generated from a control element to a heat sink and a base bracket.

According to one embodiment, it is possible to provide a vehicle control apparatus having a reduced weight and high heat dissipation performance by using a base bracket that replaces conventional heat dissipation fins.

According to one embodiment, it is possible to provide a vehicle control apparatus capable of effectively reducing stress concentration and increasing the degree of freedom of mounting conditions in a vehicle by using a plurality of brackets.

### BRIEF DESCRIPTION OF THE DRAWINGS

FIG. 1 is a perspective view of a control apparatus for a vehicle according to one embodiment of the present disclosure.

FIG. 2 is an exploded perspective view of the control apparatus for a vehicle according to one embodiment of the present disclosure.

FIG. 3 is a cross-sectional view taken along line A-A′ of FIG. 1, showing a heat dissipation path.

FIG. 4 is a cross-sectional view taken along line B-B′ of FIG. 1.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

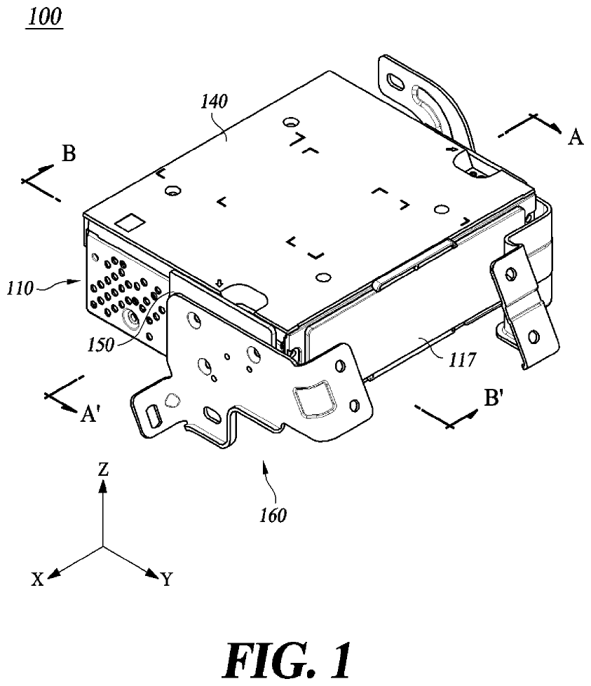

FIG. 1 is a perspective view of a control apparatus for a vehicle according to one embodiment of the present disclosure.

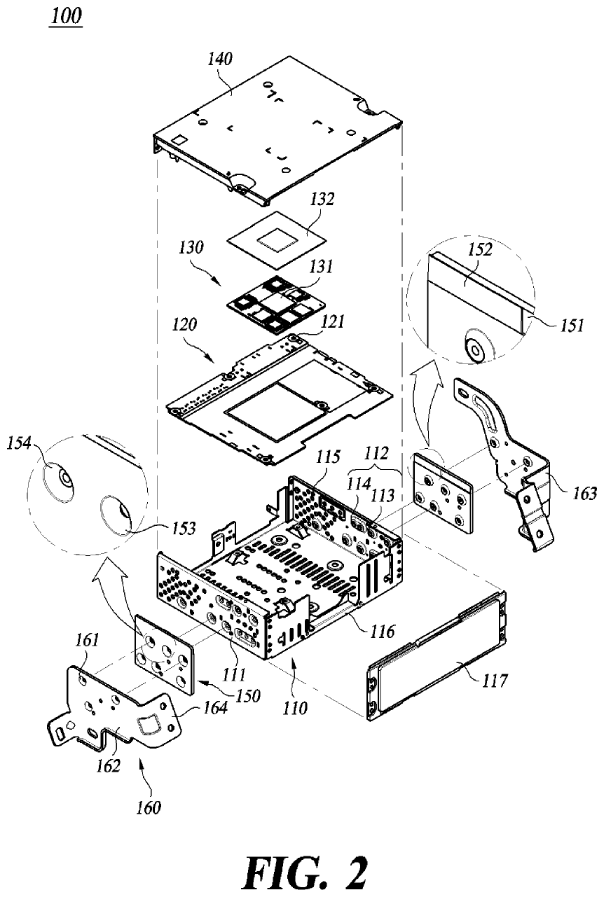

FIG. 2 is an exploded perspective view of the control apparatus for a vehicle according to one embodiment of the present disclosure.

Referring to FIG. 1 and FIG. 2, the vehicle control apparatus 100 according to an embodiment of the present disclosure includes some or all of a housing 110, a control board 120, a control element 130, a heat sink 140, a base bracket 150, and a main bracket 160.

The housing 110 forms an exterior of the vehicle control apparatus 100 and may have an internal space. The control board 120 may be installed in the internal space of the housing 110. The upper side of the housing 110 is open, and a mounting side 111 may be formed in an area of one side of the housing 110 such that the base bracket 150 which will be described later can be coupled thereto.

The mounting side 111 may include a plurality of housing fasteners 112 formed at positions corresponding to the area where the base bracket 150 and the main bracket 160 are disposed.

By fastening the base bracket 150 to the housing 110 and additionally coupling the main bracket 160 which will be described later to the base bracket 150, stress concentration applied to the housing 110 can be alleviated.

At least some of the plurality of housing fasteners 112 may be fastened to the base bracket 150. At least some other housing fasteners 112 may be disposed to correspond to the base bracket 150 and the main bracket 160.

A first mounting hole 113 that can be fastened to the base bracket 150 may be formed through an area of the plurality of housing fasteners 112. A second mounting hole 114 corresponding to the base bracket 150 and the main bracket 160 may be formed through another area of the plurality of housing fasteners 112.

The first mounting hole 113 has an inner diameter that gradually decreases toward the other surface of the plurality of housing fasteners 112. The second mounting hole 114 may have an inner diameter that gradually decreases toward the other surface of the plurality of housing fasteners 112.

Heat dissipation openings 115 may be formed in another area of one side of the housing 110 to release heat into the interior of the housing 110.

The number of heat dissipation openings 115 may be two or more according to required heat dissipation performance, and one or a plurality of heat dissipation openings 115 may be formed at various locations including the side and bottom of the housing 110 as needed.

A plurality of openings 116 may be formed in an area of the other side perpendicular to one side of the housing 110 such that heat can be released into the interior of the housing 110. A cover plate 117 covering the plurality of openings 116 may be combined with the plurality of openings 116. The cover plate 117 can prevent moisture or foreign substances from entering the interior of the housing.

The housing 110 may be formed using a material with excellent rigidity such as SECC material and may be manufactured using a press method. Here, the press method refers to processing a material using a press and performing an operation of forming or cutting the material by applying pressure thereto. This is an exemplary description of the function and the present disclosure is not limited thereto.

The control board 120 is installed in the internal space of the housing 110 and receives and processes information from sensors or switches installed in each part of the vehicle.

The control board 120 controls the functions of various systems included in the vehicle. The control board 120 processes various signals, such as an engine status and a vehicle speed, received from the inside and outside of the vehicle. The control board 120 controls various functions, such as the engine, brake, air conditioning, and windows, based on the processed information. This is an exemplary description of the functions, and the present disclosure is not necessarily limited thereto.

The control board 120 includes various components. The various components perform different functions and interact with each other to operate. The control board 120 may include a type of printed circuit board (PCB) on which electronic components (not shown) such as diodes are mounted.

The control board 120 may include a microcontroller, a microprocessor, a memory, an analog-to-digital converter (ADC), a digital-to-analog converter (DAC), a power management circuit, a signal processing circuit, and the like. However, this is an exemplary configuration, and the present disclosure is not necessarily limited thereto.

The control element 130 may be mounted on an area of one side of the control board 120. The control element 130 serves to control devices installed in each part of the vehicle, such as an electronic control unit (ECU), a head up display (HUD), a microcontroller unit (MCU), an advanced vehicle management (AVM), an infotainment system, a communication system, an autonomous driving system, and an air conditioning system.

The control element 130 includes at least one heat-generating component 131. The heat-generating component 131 may include a central processing unit (CPU), a graphic processing unit (GPU), a sensor interface (IC), etc.

In order to release heat generated from the heat-generating component 131, one side of the control element 130 may contact the heat sink 140 which will be described later to effectively release the heat.

A first thermal interface material 132 may be provided between the control element 130 and the heat sink 140 to transfer heat generated from the heat-generating component 131 to the heat sink 140.

The first thermal interface material 132 may be provided to correspond to an area of the control element 130 that includes the heat-generating component 131. The first thermal interface material 132 may be designed to function even when placed between the control element 130 and the heat sink 140 and pressed by a compressive pressure.

The first thermal interface material 132 may be a composite material based on a metal such as aluminum and a thermally conductive filler (i.e., a filling material) such as ceramic or carbon. The first thermal interface material 132 may be a heat dissipation adhesive. The heat dissipation adhesive may be attached to an object to be heat-dissipated and may perform a heat dissipation function. However, this is an exemplary configuration and the present disclosure is not necessarily limited thereto.

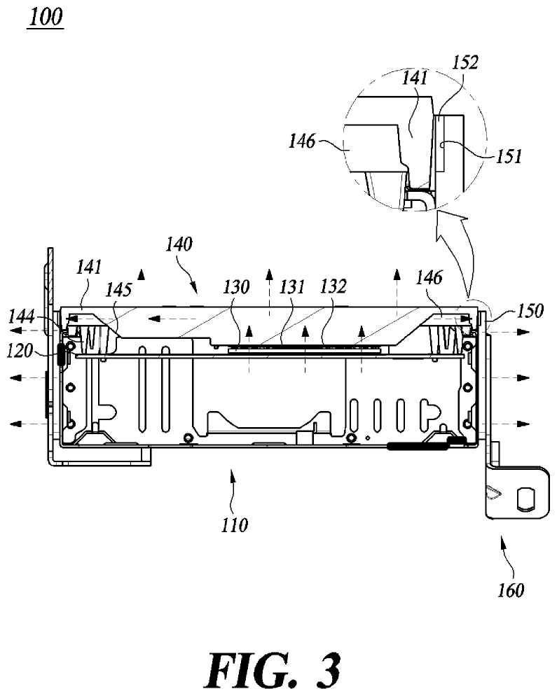

FIG. 3 is a cross-sectional view taken along line A-A′ of FIG. 1, showing a heat dissipation path.

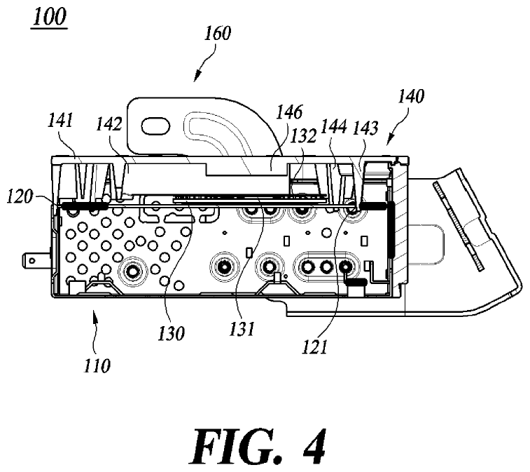

FIG. 4 is a cross-sectional view taken along line B-B′ of FIG. 1.

Referring to FIG. 3 and FIG. 4, the heat sink 140 includes all or some of a cover portion 141 and a contact portion 142.

The heat sink 140 corresponds to one side of the control board 120 and may cover the upper side of the housing 110. The heat sink 140 serves to take heat from a system that generates heat and dissipate the heat to the surroundings based on a material and structure specialized for heat conduction and radiation.

The cover portion 141 is disposed on the upper side of the housing 110. The cover portion 141 can cover the housing 110 with the open upper side.

The end of the cover portion 141 that comes into contact with the mounting side 111 may be formed to extend toward the lower part of the housing 110.

The heat sink 140 includes at least one insertion portion 143 that protrudes toward the internal space. Preferably, the insertion portion 143 may be formed on one surface of the cover portion 141. The insertion portion 143 may be formed to have an inner diameter that gradually decreases toward the internal space of the housing 110.

The control board 120 includes at least one through hole 121 formed on one surface of the control board 120.

The heat sink 140 and the control board 120 may be coupled with each other by the insertion portion 143 penetrating the through hole 121.

The cover portion 141 includes at least one heat dissipation protrusion 144 formed to protrude toward the inner space of the housing 110 to determine the position of the heat sink 140 when coupled with the housing 110. The heat dissipation protrusion 144 may be formed to have an inner diameter that gradually decreases toward the inner space of the housing 110.

The contact portion 142 may be formed to protrude from the cover portion 141 and come into contact with one surface of the first thermal interface material 132. The contact portion 142 may be formed to extend in the longitudinal direction of the housing 110 and correspond to the first thermal interface material 132.

A slope 145 may be formed at one end of the contact portion 142 such that the end is inclined downward.

The contact portion 142 may be formed to extend such that an area of the slope 145 is connected to the end of the cover portion 141 in order to release heat transferred from the contact portion 142 to the outside.

The contact portion 142 may include a heat transfer channel 146 through which heat transferred to the contact portion 142 can be directly transferred to the base bracket 150 installed outside.

A cooling fan (not shown) may be positioned inside the housing 110 to convect the air inside the housing. Convecting the air inside the housing may be achieved by drawing outside air into the housing using the cooling fan (not shown) or by discharging the air inside the housing to the outside of the housing 110 using the cooling fan (not shown).

The base bracket 150 may be disposed on one side of the housing 110. The base bracket 150 may be disposed in contact with the heat sink 140. The base bracket 150 may be disposed in an area of the joining surface where the housing 110 and the heat sink 140 are joined and may be formed to extend in the longitudinal direction of one side of the housing 110.

The base bracket 150 may be formed using a metal with high thermal conductivity, such as aluminum or an alloy thereof. Typically, aluminum is manufactured using, for example, ADC12 material and has relatively low thermal conductivity. However, aluminum described in an embodiment of the present disclosure may be formed based on AL5052P-H32 material, which is aluminum having relatively high thermal conductivity. However, this is an exemplary configuration and the present disclosure is not necessarily limited thereto.

In addition, conventional aluminum processing methods process aluminum relatively thickly using a die casting processing method and thus aluminum has relatively low thermal conductivity. In an embodiment of the present disclosure, the base bracket 150 may be manufactured using the aluminum press processing method described above and processed relatively thinly and thus has relatively high thermal conductivity. However, this is an exemplary configuration and the present disclosure is not necessarily limited thereto.

The base bracket 150 may include a second thermal interface material 152 disposed between the contact portion 142 and the base bracket 150 such that heat transferred by the contact portion 142 is transferred to the base bracket 150.

The second thermal interface material 152 may be disposed corresponding to the heat transfer channel 146 and may be formed to extend in the longitudinal direction of one side of the housing 110. The second thermal interface material 152 may be disposed between the contact portion 142 and the base bracket 150 and may be designed to function even when pressed by a compressive pressure.

The second thermal interface material 152 may be a composite material formed based on a metal such as aluminum and a thermally conductive filler (i.e., a filling material) such as ceramic or carbon. The second thermal interface material 152 may be a heat dissipation adhesive. The heat dissipation adhesive may be attached to an object to be heat-dissipated and may perform a heat dissipation function.

A groove portion 151 may be formed in an area of the upper portion of the base bracket 150. The groove portion 151 may extend in the longitudinal direction of the base bracket 150. The groove portion 151 may be formed on one side of the base bracket 150 that contacts the contact portion 142.

The second thermal interface material 152 may be provided in an area of the groove portion 151. Heat transferred from the contact portion 142 can be directly transferred to the base bracket 150 through the second thermal interface material 152 to be released to the outside.

A first fastening hole 153 may be formed to penetrate an area of one side of the base bracket 150. The first fastening hole 153 may be formed by forming. Here, the forming may include a method of extruding or molding a material to create a desired shape. However, this is an example and the present disclosure is not necessarily limited thereto.

The first fastening hole 153 may have a shape in which the inner diameter of the first fastening hole 153 gradually decreases toward the other surface of the base bracket 150. The first fastening hole 153 may be formed in an area of one side of the base bracket 150 to correspond to the first mounting hole 113 of the mounting side 111. The housing 110 may be fastened to the base bracket 150 by fastening the first fastening hole 153 to the first mounting hole 113.

A second fastening hole 154 may be formed to penetrate another area of one side of the base bracket 150. The second fastening hole 154 may have an inner diameter that gradually decreases toward the other surface of the base bracket 150. The second fastening hole 154 may be formed using tapping processing. Here, the tapping processing may mean a process of creating a tap or creating a screw for existing screw holes. However, this is an example and the present disclosure is not necessarily limited thereto.

The second fastening hole 154 may be formed in another area of one side of the base bracket 150 to correspond to the second mounting hole 114 of the mounting side 111.

The second fastening hole 154 may have a lower inner diameter narrower than the lower inner diameter of the first fastening hole 153.

The main bracket 160 may be disposed in contact with one side of the base bracket 150. The main bracket 160 may include all or some of a body portion 162, a bent portion 163, and a mounting portion 164.

The body portion 162 may be disposed to correspond to one side of the base bracket 150. A third fastening hole 161 may be formed to penetrate one side of the body portion 162. The inner diameter of the third fastening hole 161 may gradually decrease toward the other side of the body portion 162.

The third fastening hole 161 may be formed in one surface of the body portion 162 to correspond to the second mounting hole 114 of the mounting side 111 and the second fastening hole 154 of the base bracket 150.

The base bracket 150 may be fastened to the main bracket 160 by fastening the third fastening hole 161 to the second fastening hole 154.

The bent portion 163 may be formed in a bent shape between the body portion 162 and the mounting portion 164 such that the main bracket 160 can be fitted to a mounting position in the vehicle.

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

What is claimed is:

1. A control apparatus for a vehicle, the control apparatus comprising:
a housing having an internal space therein and an open upper side;
a control board mounted inside the housing;
a control element positioned on a surface of the control board and including at least one heat-generating component;
a heat sink corresponding to a surface of the control board and covering the open upper side of the housing;
a base bracket mounted on one side of the housing and contacting the heat sink to release heat to an outside of the control apparatus; and
a main bracket in contact with a surface of the base bracket.

2. The control apparatus of claim 1, wherein the base bracket is formed to extend in a longitudinal direction along one side of the housing from an area of a joining surface where the housing and the heat sink are joined.

3. The control apparatus of claim 1, further including a first thermal interface material disposed between the control element and the heat sink to transfer heat generated from the at least one heat-generating component to the heat sink.

4. The control apparatus of claim 3, wherein the heat sink includes:
a cover portion disposed on the open upper side of the housing; and
a contact portion formed to protrude from the cover portion and to contact with a surface of the first thermal interface material.

5. The control apparatus of claim 4, wherein the cover portion includes at least one heat dissipation protrusion formed to protrude toward the inner space of the housing to determine a position of the heat sink when coupled with the housing.

6. The control apparatus of claim 4,
wherein the contact portion extends in the longitudinal direction of the housing and has a slope formed at one end of the contact portion so that the one end is inclined downward, and
wherein the contact portion is formed to extend so that an area of the slop is connected to an end of the cover portion to transfer heat to the base bracket.

7. The control apparatus of claim 4, wherein the contact portion includes a heat transfer channel through which heat transferred to the contact portion is directly transferred to the base bracket.

8. The control apparatus of claim 7, further including a second thermal interface material disposed between the contact portion and the base bracket and disposed corresponding to the heat transfer channel.

9. The control apparatus of claim 1,
wherein the control board includes at least one through hole formed on a surface of the control board, and the heat sink includes at least one insertion portion formed to protrude toward the internal space,
wherein the control board is coupled with the heat sink by the at least one insertion portion penetrating the at least one through hole.

10. The control apparatus of claim 6, further including a second thermal interface material disposed between the contact portion and the base bracket so that heat transferred by the contact portion is transferred to the base bracket.

11. The control apparatus of claim 10, wherein the base bracket includes a groove portion formed in an area of an upper portion of the base bracket and the second thermal interface material is disposed in the groove portion.

12. The control apparatus of claim 11, wherein the groove portion is formed on one side of the base bracket that contacts the contact portion.

13. The control apparatus of claim 1, wherein the housing includes a first mounting hole formed at a position corresponding to a first fastening hole formed in an area of a surface of the base bracket and is fastened to the base bracket by fastening the first fastening hole to the first mounting hole.

14. The control apparatus of claim 13, wherein an inner diameter of the first fastening hole decreases toward a surface of the base bracket.

15. The control apparatus of claim 13, wherein the base bracket includes a second fastening hole formed at a position corresponding to a third fastening hole formed in a surface of the main bracket and is fastened to the main bracket by fastening the third fastening hole to the second fastening hole.

16. The control apparatus of claim 15, wherein an inner diameter of the second fastening hole decreases toward a surface of the base bracket.

17. The control apparatus of claim 15,
wherein the main bracket includes a body portion, and
wherein an inner diameter of the third fastening hole decreases toward a side of the body portion.
